(19) United States
(12) Patent Application Publication
(10) Pub. No.: US 2024/0282799 A1
(43) Pub. Date: Aug. 22, 2024

(54) IMAGE SENSOR WITH TRANSISTOR HAVING HIGH RELATIVE PERMITTIVITY

(71) Applicant: Taiwan Semiconductor Manufacturing Company, Ltd., Hsinchu (TW)

(72) Inventors: Chih-Kuan Yu, Nantou County (TW); U-Ting Chiu, Hsinchu (TW); Shen-Hui Hong, Tainan City (TW); Feng-Chi Hung, Chu-Bei City (TW); Jen-Cheng Liu, Hsin-Chu City (TW); Dun-Nian Yaung, Taipei City (TW)

(21) Appl. No.: 18/170,030

(22) Filed: Feb. 16, 2023

(51) Int. Cl. H01L 27/146; H04N 25/79

(52) U.S. Cl. CPC H01L 27/14643; H01L 27/14612; H01L 27/14689; H04N 25/79

(57) ABSTRACT

Various embodiments of the present disclosure are directed towards an image sensor including a first chip stacked with a second chip. The first chip comprises a first substrate and a photodetector disposed in the first substrate. A first transistor is disposed on the first substrate and neighbors the photodetector. A plurality of second transistors is disposed within or on the stacked first and second chips. The plurality of second transistors comprises a first readout transistor having a first readout gate electrode over a first readout gate dielectric structure. The first readout gate dielectric structure comprises a lower dielectric layer stacked with an upper dielectric structure. A relative permittivity of the upper dielectric structure is greater than a relative permittivity of the lower dielectric layer.

### BACKGROUND

Many modern-day electronic devices (e.g., smartphones, digital cameras, biomedical imaging devices, automotive imaging devices, etc.) comprise image sensors. The image sensors comprise one or more photodetectors (e.g., photodiodes, phototransistors, photoresistors, etc.) configured to absorb incident radiation and output electrical signals corresponding to the incident radiation. Some types of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost. Some types of CMOS image sensors include front-side illuminated (FSI) image sensors and backside illuminated (BSI) image sensors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a circuit diagram of some embodiments of an image sensor comprising a transistor having a gate dielectric structure with high relative permittivity.

FIGS. 2A and 2B illustrate various views of some embodiments of the image sensor of FIG. 1.

FIGS. 3A-3G illustrate various cross-sectional views of some other embodiments of transistors of the image sensor of FIGS. 2A and 2B.

FIG. 4 illustrates a cross-sectional view of some other embodiments of the image sense of FIGS. 2A and 2B.

FIG. 5 illustrates a circuit diagram of some other embodiments of the image sensor of FIG. 1.

FIG. 6 illustrates a cross-sectional view of some other embodiments of the image sensor of FIGS. 2A and 2B.

FIGS. 7-18 illustrate various cross-sectional views of some embodiments of a method for forming an image sensor comprising a transistor having a gate dielectric structure with high relative permittivity.

FIG. 19 illustrates a flowchart according to some embodiments of a method for forming an image sensor comprising a transistor having a gate dielectric structure with high relative permittivity.

FIG. 20 illustrates a flowchart according to some other embodiments of a method for forming an image sensor comprising a transistor having a gate dielectric structure with high relative permittivity.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacked complementary metal-oxide semiconductor (CMOS) image sensor may comprise an imaging chip and a logic chip that are stacked. The imaging chip comprises a plurality of pixel sensors that each include a photodetector, and the logic chip comprises a plurality of logic devices that may be configured as an application-specific integrated circuit (ASIC). The photodetector is configured to accumulate charge in response to incident radiation.

Further, a pixel circuit may be disposed on the imaging chip and comprises a plurality of transistors (e.g., a transfer transistor, a reset transistor, a source-follower transistor, a row-select transistor, etc.) configured to facilitate readout of the accumulated charge.

Features of the image sensor may be scaled down to increase device density, lower fabrication costs, increase performance, etc. For example, it has been appreciated that reducing a thickness of a gate dielectric structure of the source-follower transistor in the pixel circuit to a relatively low value (e.g., less than about 35 angstroms) may increase noise performance (e.g., reduce random telegraph noise) of the image sensor. However, the gate dielectric structure may have a low relative permittivity (e.g., about 3.9) such that the relatively low thickness of the gate dielectric structure may result in higher gate leakage and/or worse reliability in the source-follower transistor. As a result, an overall performance of the pixel circuit may be reduced, thereby decreasing performance of the image sensor.

Various embodiments of the present application are directed towards an image sensor comprising a pixel circuit with a transistor having relatively low equivalent oxide thickness (EOT) and improved noise performance. The image sensor may comprise an imaging chip stacked with a logic chip. The imaging chip comprises a plurality of photodetectors and a pixel circuit disposed on a substrate. The pixel circuit comprises a plurality of transistors that is configured to facilitate readout of the accumulated charge. The plurality of transistors includes a first readout transistor that may, for example, be configured as a source-follower transistor. The first transistor has a gate dielectric structure comprising a lower dielectric layer stacked with an upper dielectric structure that comprises one or more upper dielectric layer(s). The one or more upper dielectric layer(s) have a high relative permittivities (e.g., greater than that of the lower dielectric layer) and may be relatively thick (e.g., having thickness(es) greater than the lower dielectric layer). The high relative permittivities of the one or more upper dielectric layer(s) decreases the EOT of the gate dielectric structure, thereby increasing a noise performance (e.g., reduces random telegraph noise) of the first transistor. In addition, the relatively high thickness(es) of the one or more upper dielectric layer(s) decreases gate leakage in the first transistor, thereby increasing a stability and reliability of the pixel circuit. By virtue of the gate dielectric structure of the first transistor having the relatively low EOT, noise performance of the pixel circuit may be increased (e.g., reduced random telegraph noise) while increasing reliability of the first transistor. As a result, an overall performance of the image sensor is increased.

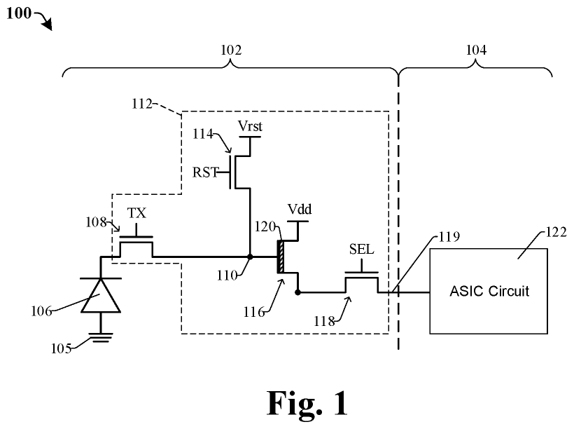

FIG. 1 illustrates a circuit diagram 100 of some embodiments of an image sensor comprising a transistor having a gate dielectric structure with high relative permittivity. The image sensor comprises an imaging chip 102 and a logic chip 104.

In some embodiments, the imaging chip 102 comprises a pixel sensor having a pixel circuit 112 and a photodetector 106 disposed on/within the imaging chip 102. The pixel circuit 112 comprises a first transistor 108 and a plurality of second transistors 114-118. The logic chip 104 comprises an ASIC circuit 122. The imaging chip 102 is configured to conduct readout of the photodetector 106 such that charge accumulated by the photodetector 106 from incident radiation may be readout as a corresponding electrical signal at an output 119 of the imaging chip 102. The electrical signal may be provided to the ASIC circuit 122 for downstream signal processing. For example, the ASIC circuit 122 may be configured to perform analog-to-digital conversion (ADC), image processing, buffering, the like, or any combination of the foregoing.

The photodetector 106 may be photodiode and is electrically coupled between ground 105 and a first source/drain terminal of the first transistor 108. An anode of the photodetector 106 is electrically coupled to ground 105, and a cathode of the photodetector 106 is electrically coupled to the first terminal of the first transistor 108. In some embodiments, the photodetector 106 is a type of photodetector other than a photodiode. The first transistor 108 may be configured as a transfer transistor that is gated by a transfer signal TX and is configured to selectively transfer accumulated charge at the photodetector 106 to a floating diffusion node 110. Further, a second source/drain terminal of the first transistor 108 is coupled to the floating diffusion node 110. Source/drain terminal(s) may refer to a source or a drain, individually or collectively dependent upon the context.

The plurality of second transistors 114-118 comprises a reset transistor 114, a source-follower transistor 116, and a select transistor 118. Further, the plurality of second transistors 114-118 may be referred to as readout transistors. The reset transistor 114 has a first source/drain terminal coupled to a reset voltage Vrst and a second source/drain terminal coupled to the floating diffusion node 110. Further, the reset transistor 114 is gated by a reset signal RST and is configured to selectively electrically coupled the floating diffusion node 110 to the reset voltage Vrst. Thus, the reset transistor 114 is configured to clear accumulated charge at the floating diffusion node 110 by electrically coupling the floating diffusion node 110 to the reset voltage Vrst. In addition, the reset transistor 114 may be configured to selectively couple the photodetector 106 to the reset voltage Vrst through coordination with the first transistor 108, thereby clearing accumulated charge at the photodetector 106.

The source-follower transistor 116 has a first source/drain terminal coupled to a power supply voltage Vdd and a second source/drain terminal coupled to the select transistor 118. The source-follower transistor 116 is gated by a charge at the floating diffusion node 110.

For instance, a gate of the source-follower transistor 116 is directly electrically coupled to the floating diffusion node 110 and/or the second source/drain terminal of the first transistor 108. Further, the select transistor 118 has a first source/drain terminal coupled to the second source/drain terminal of the source-follower transistor 116 and a second source/drain terminal coupled to the output 119 of the imaging chip 102. Thus, the source-follower transistor 116 and the select transistor 118 are coupled in series from the power supply voltage Vdd to the output 119. In some embodiments, the source-follower transistor 116 is configured to buffer and/or amplify a voltage at the floating diffusion node 110 for non-destructive reading of the voltage. The select transistor 118 is configured to selectively pass the buffered and/or amplified voltage from the source-follower transistor 116 to the output 119. This buffered and/or amplified voltage is then passed to the ASIC circuit 122 of the logic chip 104 for downstream signal processing.

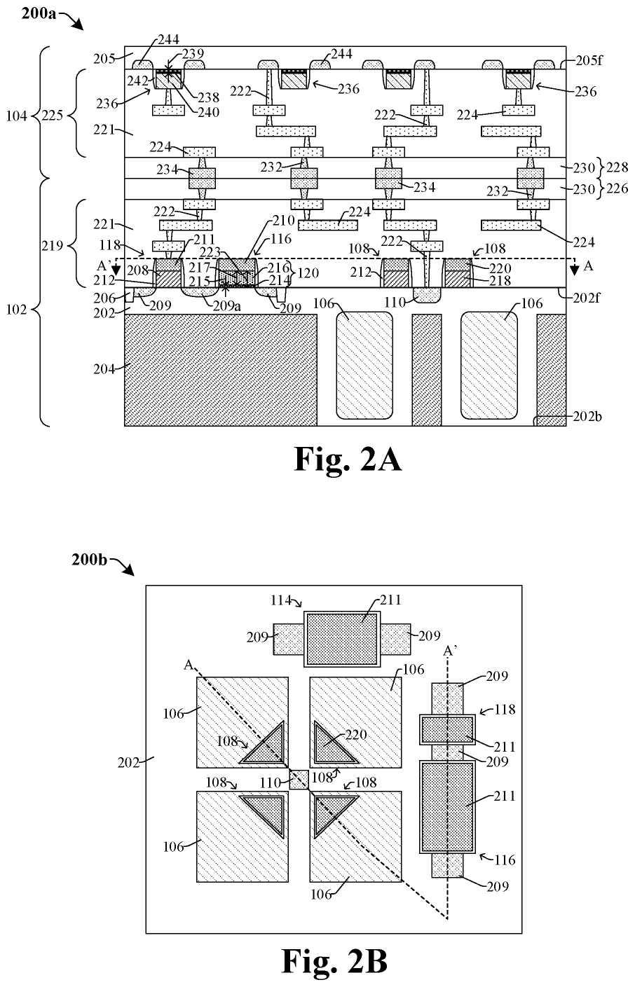

In various embodiments, during operation of the pixel circuit 112 noise may be present in the second plurality of transistors 114-118. For example, it has been appreciated that noise (such as random telegraph noise) may be present in the buffered and/or amplified voltage at the second source/drain terminal of the source-follower transistor 116. Accordingly, various embodiments of the present application are directed towards the first readout gate dielectric structure 120 of the source-follower transistor 116 having a relatively low equivalent oxide thickness (EOT) (e.g., less than or equal to about 30 angstroms) to increase noise performance (e.g., reduce random telegraph noise). For example, the EOT of the first readout gate dielectric structure 120 of the source-follower transistor 116 may be less than EOTs of gate dielectric structures of the first transistor 108, the reset transistor 114, the select transistor 118, and/or transistors of the ASIC circuit 122. The relatively low EOT of the first readout gate dielectric structure 120 increases noise performance (e.g., by reducing random telegraph noise) of the pixel circuit 112 while increasing reliability of the source-follower transistor 116. For example, the first readout gate dielectric structure 120 of the source-follower transistor 116 comprises a lower dielectric layer stacked with an upper dielectric structure (not shown) (see FIGS. 2A and 2B). The upper dielectric structure includes one or more upper dielectric layer(s) that has/have high relative permittivities (e.g., greater than that of the lower dielectric layer) and may be relatively thick (e.g., having thickness(es) greater than the lower dielectric layer) (as illustrated and/or described in FIGS. 2A and 2B). The high relative permittivities of the one or more upper dielectric layer(s) decreases the EOT of the first readout gate dielectric structure 120. As a result, a gate dielectric capacitance of the source-follower transistor 116 is increased, thereby increasing noise performance (e.g., reduced random telegraph noise) of the source-follower transistor 116. Further, the relatively thick upper dielectric layer(s) reduces gate leakage in the source-follower transistor 116, thereby increasing a performance and reliability of the source-follower transistor 116. Therefore, the source-follower transistor 116 having the first readout gate dielectric structure 120 with relatively low EOT increases an overall performance of the image sensor.

FIGS. 2A and 2B illustrate various views of some embodiments of the image sensor of FIG. 1. FIG. 2A illustrates a cross-sectional view 200a of some embodiments of the image sensor taken along line A-A′ of top view 200b of FIG. 2B.

In some embodiments, the image sensor comprises the imaging chip 102 stacked with the logic chip 104. The imaging chip 102 comprises an imaging substrate 202, an imaging interconnect structure 219 disposed on a front side 202f of the imaging substrate 202, and an imaging bond structure 226 disposed on the imaging interconnect structure 219. The imaging substrate 202 may, for example, be or comprise a semiconductor body (e.g., monocrystalline silicon, CMOS bulk, silicon-germanium, etc.) and has a first doping type (e.g., p-type). A plurality of photodetectors 106 is disposed within the imaging substrate 202. The photodetectors 106 may have a second doping type (e.g., n-type) opposite the first doping type (e.g., p-type). In some embodiments, the first doping type is p-type and the second doping type is n-type, or vice versa. A floating diffusion node 110 is disposed within the imaging substrate 202 and may comprise the second doping type (e.g., n-type). The floating diffusion node 110 is disposed between adjacent photodetectors in the plurality of photodetectors 106.

A first isolation structure 206 extends into the front side 202f of the imaging substrate 202 and a second isolation structure 204 extends into a back side 202b of the imaging substrate 202. The first isolation structure 206 is configured as a shallow trench isolation (STI) structure and may be or comprise silicon dioxide, silicon nitride, silicon carbide, another dielectric material, or any combination of the foregoing. The second isolation structure 206 may be configured as a back-side deep trench isolation (DTI) structure an may be or comprise a dielectric material such as silicon dioxide, silicon nitride, aluminum oxide, etc., a metal material such as tungsten, aluminum, titanium, etc., some other suitable material, or any combination of the foregoing. Further, the second isolation structure 204 is spaced laterally between adjacent photodetectors in the photodetectors 106 and is configured to increase electrical and/or optical isolation between the photodetectors 106.

Further, a plurality of first transistors 108 is disposed on the front side 202f of the imaging substrate 202. The plurality of first transistors 108 may each be configured as transfer transistors that are configured to transfer accumulated charge from the photodetectors 106 to the floating diffusion node 110. The plurality of first transistors 108 each comprise a transfer gate dielectric structure 218 and a transfer gate electrode 220 on the transfer gate dielectric structure 218. In addition, a plurality of second transistors 114-118 is disposed on the front side 202f of the imaging substrate 202. The plurality of second transistors 114-118 are configured to conduct readout of the accumulated charge of the photodetectors 106 and may be referred to as readout transistors. The plurality of second transistors 114-118 comprise a reset transistor 114, a source-follower transistor 116, and a select transistor 118. The source-follower transistor 116 comprises a first readout gate dielectric structure 120 disposed on the front side 202f of the imaging substrate 202, a first readout gate electrode 210 on the first readout gate dielectric structure 120, and source/drain regions 209 disposed on opposing sides of the first readout gate dielectric structure 120. Further, the reset transistor 114 and the select transistor 118 each comprise a second readout gate dielectric structures 208 stacked with a second readout gate electrode 211 and source/drain regions 209 disposed on opposing sides of the second readout gate dielectric structure 208. In addition, a sidewall spacer 212 is disposed along opposing sidewalls of the individual gate structures of the plurality of first transistors 108 and the plurality of second transistors 114-118. In various embodiments, the first and second transistors 108, 114-118 are metal-oxide-semiconductor field-effector transistors (MOSFETs), fin field-effect transistors (FinFETs), gate-all-around field-effect transistors (GAA FETs), nanosheet field-effect transistors, the like, or any combination of the foregoing. In yet further embodiments, the select transistor 118 and the source-follower transistor 116 share a first source/drain region 209a disposed laterally between the second readout gate electrode 211 of the select transistor 118 and the first readout gate electrode 210 of the source-follower transistor 116. Source/drain region(s) may refer to a source or a drain, individually or collectively dependent upon the context.

The imaging interconnect structure 219 overlies the front side 202f of the imaging substrate 202 and is configured to provide electrical coupling between components of the imaging chip 102. Further, the imaging bond structure 226 is disposed on the imaging interconnect structure 219 and facilitates electrical connections between the imaging interconnect structure 219 and the logic chip 104.

The logic chip 104 comprises a logic substrate 205, a logic interconnect structure 225 disposed on the logic substrate 205, and a logic bond structure 228 disposed on the logic interconnect structure 225. The logic substrate 205 may, for example, be or comprise monocrystalline silicon, CMOS bulk, silicon-germanium, a silicon-on-insulator, some other suitable semiconductor body, or the like. A plurality of logic devices 236 is disposed on a front side 205f of the logic substrate 205. In some embodiments, embodiments, the logic devices 236 are MOSTFETs, FinFETs, GAA FETS, nanosheet field-effect transistors, the like, or any combination of the foregoing. The logic devices 236 each comprise a logic gate dielectric structure 238 disposed on the logic substrate 205, a logic gate electrode 240 disposed on the logic gate dielectric structure 238, a pair of source/drain regions 244 disposed on opposing sides of the logic gate electrode 240, and a logic sidewall spacer 242 disposed along sidewalls of the logic gate electrode 240 and the logic gate dielectric structure 238. The logic interconnect structure 225 is configured to facilitate electrical connections between the logic devices 236 and the logic bond structure 228. Further, the logic bond structure 228 facilitates electrical connections between the logic interconnect structure 225 and the imaging chip 102.

In various embodiments, the imaging interconnect structure 219 and the logic interconnect structure 225 each comprise a plurality of conductive vias 222 and a plurality of conductive wires 224 disposed within an interconnect dielectric structure 221. The interconnect dielectric structure 221 may comprise a plurality of dielectric layers that may, for example, be or comprise silicon dioxide, a low-k dielectric material, an extreme low-k dielectric material, some other dielectric material, or any combination of the foregoing. The conductive vias and wires 222, 224 may, for example, be or comprise copper, aluminum, titanium nitride, tantalum nitride, tungsten, ruthenium, some other conductive material, or any combination of the foregoing. The imaging bond structure 226 and the logic bond structure 228 each comprise a plurality of bond contacts 232 and a plurality of bond pads 234 disposed within a bond dielectric structure 230. In various embodiments, the imaging bond structure 226 and the logic bond structure 228 meet at a first bonding interface that comprises dielectric-to-dielectric bonds and metal-to-metal bonds. The bond contacts 232 and the bond pads 234 may, for example, be or comprise copper, tungsten, titanium, tantalum, some other conductive material, or any combination of the foregoing. Further, the bond dielectric structure 230 may, for example, be or comprise an oxide (e.g., silicon dioxide), silicon nitride, silicon carbide, silicon oxynitride, some other dielectric material, or any combination of the foregoing.

The logic gate electrode 240 may, for example, be or comprise polysilicon, doped polysilicon, titanium, titanium nitride, tantalum, tungsten, aluminum, some other suitable conductive material(s), or any combination of the foregoing. The logic gate dielectric structure 238 may, for example, be or comprise silicon oxide, hafnium oxide, zirconium oxide, or some other suitable dielectric material(s). In some embodiments, the logic gate dielectric structure 238 comprises a dielectric material (e.g., silicon oxide) with a low relative permittivity (e.g., about 3.9 or less). In such embodiments, a thickness 239 of the logic gate dielectric structure 238 is within a range of about 22 angstroms to about 70 angstroms, or some other suitable value. In yet further embodiments, the logic gate dielectric structure 238 comprises a dielectric material (e.g., hafnium oxide, zirconium oxide, etc.) with a high relative permittivity (e.g., greater than 3.9, within a range of about 9 to 25, etc.). In such embodiments, the thickness 239 of the logic gate dielectric structure 238 is less than or equal to 30 angstroms, within a range of about 5 to about 30 angstroms, or some other suitable value. In various embodiments, the thickness 239 of the logic gate dielectric structure 238 corresponds to a height of the logic gate dielectric structure 238 and is defined between a top surface and a bottom surface of the logic gate dielectric structure 238.

The first readout gate electrode 210 and the second readout gate electrode 211 may, for example, be or comprise polysilicon, doped polysilicon, titanium nitride, tantalum, tungsten, aluminum, some other suitable conductive material(s), or any combination of the foregoing. The first readout gate dielectric structure 120 comprises a lower dielectric layer 214 and an upper dielectric structure 216. In some embodiments, the lower dielectric layer 214 comprises a first dielectric material (e.g., silicon oxide) having a low relative permittivity (e.g., about 3.9 or less) and has a thickness 215. In some instances, the thickness 215 of the lower dielectric layer 214 is relatively low and may be about 15 angstroms, less than about 15 angstroms, within a range of about 5 to about 15 angstroms, or some other suitable value. Further, the upper dielectric structure 216 comprises one or more upper dielectric layer(s) comprising a second dielectric material (e.g., hafnium oxide, zirconium oxide, aluminum oxide, silicon nitride, etc.) having a high relative permittivity (e.g., within a range of about 9 to 25, greater than 3.9, etc.) and has a thickness 217. In some instances, the thickness 217 is relatively high and may be about 40 angstroms, less than about 96 angstroms, within a range of about 20 angstroms to about 96 angstroms, or some other suitable value.

The lower dielectric layer 214 and the upper dielectric structure 216 collectively provide for an equivalent oxide thickness (EOT) of the first readout gate dielectric structure 120 of the source-follower transistor 116. The EOT is the thickness of a silicon oxide (e.g., SiO₂) gate dielectric layer used to obtain the same gate capacitance as the one obtained with thicker than SiO₂ dielectric featuring higher relative permittivity ϵᵣ (e.g., an EOT of 1 angstrom would result from the use a 10 angstrom thick dielectric featuring ϵᵣ=39 (ϵᵣ of SiO₂ is 3.9)). While EOT scaling issues (e.g., high gate leakage, low reliability, etc.) may arise with gate dielectric structures having a low relative permittivity (e.g., about 3.9 or less), such scaling issues are mitigated with the stacked lower dielectric layer 214 and the upper dielectric structure 216. This is because the high relative permittivity of the upper dielectric structure 216 decreases the EOT of the first readout gate dielectric structure 120. For example, the EOT of the first readout gate dielectric structure 120 is determined by the equation: EOT=((215*1/ϵᵣ₁)+(217*1/ϵᵣ₂))*ϵ_{r of SiO2}), where ϵᵣ₁ corresponds to the relative permittivity of the lower dielectric layer 214 and ϵᵣ₂ corresponds to the relative permittivity of the upper dielectric structure 216. In an embodiment, the lower dielectric layer 214 comprises SiO₂, the thickness 215 of the lower dielectric layer 214 is 15 angstroms, the upper dielectric structure 216 is a single layer comprising hafnium oxide (e.g., HfO₂), and the thickness 217 is 40 angstroms such that the EOT of the first readout gate dielectric structure 120 is determined by the equation: EOT=((15*1/3.9)+(40*1/25))*3.9. In such instances, the EOT of the first readout gate dielectric structure 120 is approximately 21.24 angstroms. Accordingly, the relatively low EOT (e.g., less than 35 angstroms) of the first readout gate dielectric structure 120 increases noise performance of the source-follower transistor 116 (e.g., by reducing random telegraph noise). Further, the relatively large thickness 217 (e.g., greater than 20 angstroms) of the upper dielectric structure 216 decreases gate leakage in the source-follower transistor 116 and increases an overall reliability of the source-follower transistor 116. Thus, the first readout gate dielectric structure 120 having the relatively low EOT increases noise performance and a reliability of the image sensor.

In various embodiments, the second readout gate dielectric structure 208 and the transfer gate dielectric structure 218 may each be configured as the first readout gate dielectric structure 120. For example, the second readout gate dielectric structure 208 and the transfer gate dielectric structure 218 respectively comprise the lower dielectric layer 214 and the upper dielectric structure 216 (not shown). In such embodiments, the first transistors 108 and the second transistors 114-118 may be formed concurrently with one another thereby reducing manufacturing costs. In further embodiments, the second readout gate dielectric structure 208 and the transfer gate dielectric structure 218 may each comprises a single dielectric layer (e.g., comprising silicon dioxide) and may each have a thickness within a range of about 22 angstroms to about 70 angstroms or some other value. In such embodiments, relative permittivities of the second readout gate dielectric structure 208 and the transfer gate dielectric structure 218 are each less than the relative permittivity of the upper dielectric structure 216, EOTs of the second readout gate dielectric structure 208 and the transfer gate dielectric structure 218 are each less than the EOT of the first readout gate dielectric structure 120, and thicknesses of the second readout gate dielectric structure 208 and the transfer gate dielectric structure 218 are each less than a thickness 223 of the first readout gate dielectric structure 120.

In yet further embodiments, the thickness 239 of the logic gate dielectric structure 238 is less than the thickness 223 of the first readout gate dielectric structure 120. In some embodiments, the logic gate dielectric structure 238 and the lower dielectric layer 214 comprise a same material (e.g., SiO₂) and the thickness 239 of the logic gate dielectric structure 238 is greater than the thickness 215 of the lower dielectric layer 214. In various embodiments, a relative permittivity of the logic gate dielectric structure 238 is higher than, lower than, or equal to the relative permittivity of the lower dielectric layer 214 and/or the relative permittivity of the upper dielectric structure 216.

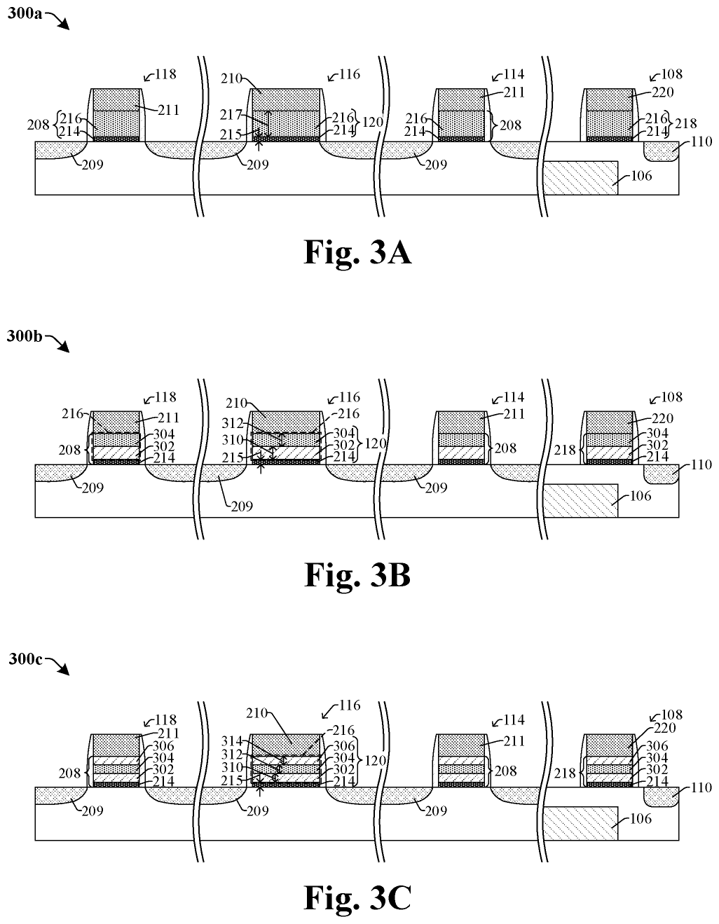

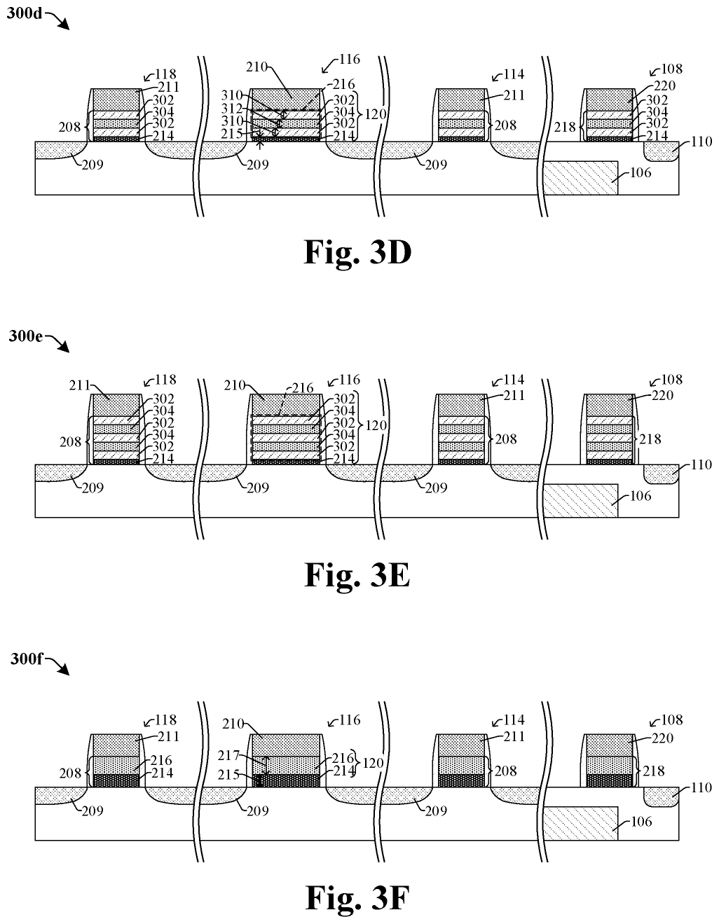

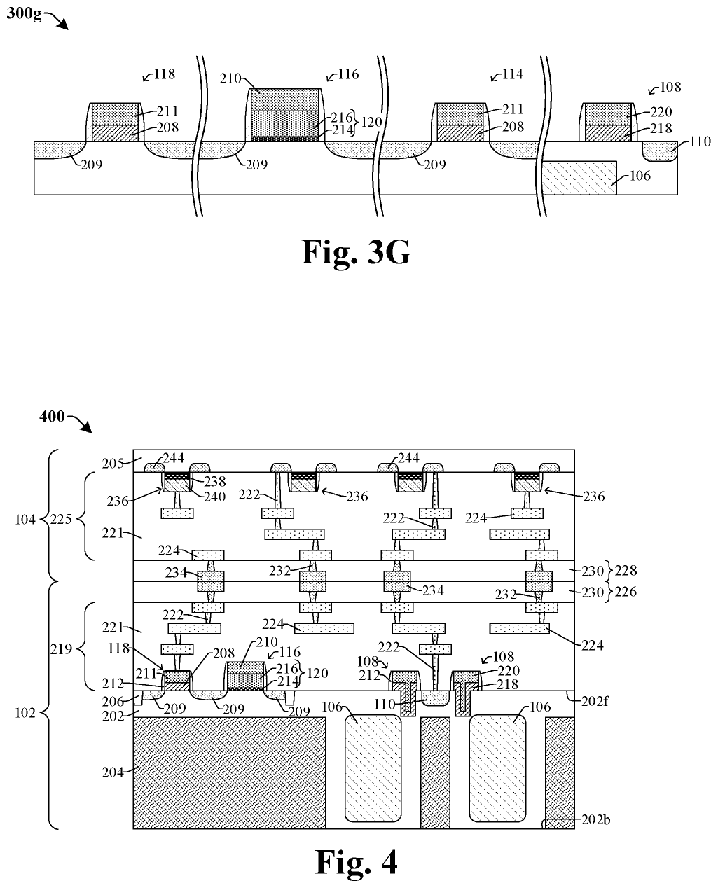

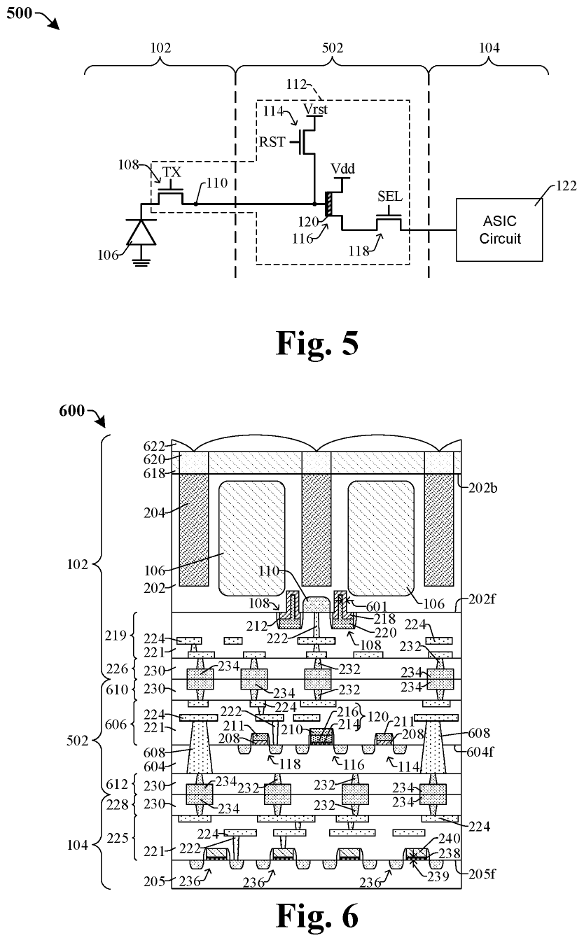

FIGS. 3A-3G illustrate cross-sectional views 300a-300g of some alternative embodiments of the first and second transistors 108 and 114-118 of FIGS. 2A and 2B.

With reference to the cross-sectional view 300a of FIG. 3A, the transfer gate dielectric structure 218, the first readout gate dielectric structure 120, and the second readout gate dielectric structure 208 respectively comprise the lower dielectric layer 214 and the upper dielectric structure 216. In some embodiments, the lower dielectric layer 214 comprises a first dielectric material (e.g., silicon dioxide) and has a thickness 215 that may be about 15 angstroms, less than about 15 angstroms, within a range of about 5 to about 15 angstroms, or some other suitable value. In various embodiments, the upper dielectric structure 216 comprises a second dielectric material (e.g., hafnium oxide (HfO₂), zirconium oxide (ZrO₂), aluminum oxide (Al₂O₃), silicon nitride (Si₃N₄), etc. and has a thickness 217 that may be about 20 angstroms, about 40 angstroms, less than about 96 angstroms, within a range of about 20 angstroms to about 96 angstroms, or some other suitable value. In various embodiments, the first dielectric material is different from the second dielectric material and the thickness 215 is less than the thickness 217. Further, a relative permittivity of the lower dielectric layer 214 is less than a relative permittivity of the upper dielectric structure 216. For example, the relative permittivity of the lower dielectric layer 214 may be about 3.9 and the relative permittivity of the upper dielectric structure 216 may be about 25. In yet further embodiments, the upper dielectric structure 216 is a single material, where the single material may, for example, be or hafnium oxide, silicon nitride, zirconium oxide, or the like.

With reference to the cross-sectional view 300b of FIG. 3B, the transfer gate dielectric structure 218, the first readout gate dielectric structure 120, and the second gate dielectric structure 208 respectively comprise the lower dielectric layer 214 and the upper dielectric structure 216, where the upper dielectric structure 216 comprises two or more upper dielectric layers. In various embodiments, the upper dielectric structure 216 comprises a first upper dielectric layer 302 and a second upper dielectric layer 304. In some embodiments, the lower dielectric layer 214 comprises a first dielectric material (e.g., silicon dioxide), the first upper dielectric layer 302 comprises a second dielectric material (e.g., aluminum oxide (Al₂O₃)), and the second upper dielectric layer 304 comprises a third dielectric material (e.g., zirconium oxide (ZrO₂), where the first dielectric material, second dielectric material, and third dielectric material are each different from one another. Relative permittivities of the first and second upper dielectric layer 302, 304 are each greater than a relative permittivity of the lower dielectric layer 214. In further embodiments, the relative permittivity of the first upper dielectric layer 302 is less than the relative permittivity of the second upper dielectric layer 304.

A thickness 310 of the first upper dielectric layer 302 is about 20 angstroms, within a range of about 15 angstroms to about 48 angstroms, or some other suitable value. A thickness 312 of the second upper dielectric layer 304 is about 20 angstroms, within a range of about 15 angstroms to about 48 angstroms, or some other suitable value. Further, the thickness 310, 312 of the first and second upper dielectric layers 302, 304 are greater than the thickness 215 of the lower dielectric layer 214. In an embodiment, the relative permittivity of the lower dielectric layer 214 is about 3.9 and the thickness 215 is about 15 angstroms, the relative permittivity of the first upper dielectric layer 302 is about 9 and the thickness 310 is about 20 angstroms, and the relative permittivity of the second upper dielectric layer 304 is about 25 and the thickness 312 is about 20 angstroms, such that the EOT of the first readout gate dielectric structure 120 is about 26.8 angstroms.

With reference to the cross-sectional view 300c of FIG. 3C, the transfer gate dielectric structure 218, the first readout gate dielectric structure 120, and the second gate dielectric structure 208 respectively comprise the lower dielectric layer 214 and the upper dielectric structure 216, where the upper dielectric structure 216 comprises three or more upper dielectric layers. In various embodiments, the upper dielectric structure 216 comprises the first upper dielectric layer 302, the second upper dielectric layer 304, and a third upper dielectric layer 306. The lower dielectric layer 214 comprises the first dielectric material (e.g., silicon dioxide), the first upper dielectric layer 302 comprises the second dielectric material (e.g., aluminum oxide (Al₂O₃)), the second upper dielectric layer 304 comprises the third dielectric material (e.g., zirconium oxide (ZrO₂), and the third upper dielectric layer 306 comprises a fourth dielectric material (e.g., hafnium oxide (HfO₂). In some embodiments, the first dielectric material, second dielectric material, third dielectric material, and fourth dielectric material are each different from one another.

Relative permittivities of the first, second, and third upper dielectric layers 302-306 are each greater than a relative permittivity of the lower dielectric layer 214. In further embodiments, the relative permittivity of the first upper dielectric layer 302 is less than the relative permittivities of the second and third upper dielectric layers 304, 306. A thickness 314 of the third upper dielectric layer 306 is about 15 angstroms, within a range of about 15 angstroms to about 48 angstroms, or some other suitable value. In further embodiments, the thicknesses 310-314 of the first, second, and third upper dielectric layers 302-306 are each greater than the thickness 215 of the lower dielectric layer 214. In yet further embodiments, by virtue of the upper dielectric structure 216 comprising the first, second, and third upper dielectric layers 302-306 that each have a high relative permittivity (e.g., greater than about 3.9), the EOT of the first readout gate dielectric structure 120 is relatively low (i.e., less than about 30 angstroms). In yet further embodiments, relative permittivities of the first, second, and third upper dielectric layers 302, 304, 306 may be larger than, less than, or equal to each other.

With reference to the cross-sectional view 300d of FIG. 3D, the transfer gate dielectric structure 218, the first readout gate dielectric structure 120, and the second gate dielectric structure 208 respectively comprise the lower dielectric layer 214 and the upper dielectric structure 216, where the upper dielectric structure 216 comprises a second upper dielectric layer 304 stacked between first upper dielectric layers 302. The lower dielectric layer 214 comprises the first dielectric material (e.g., silicon dioxide), the first upper dielectric layers 302 comprise the second dielectric material (e.g., aluminum oxide (Al₂O₃)), and the second upper dielectric layer 304 comprises the third dielectric material (e.g., zirconium oxide (ZrO₂). In some embodiments, the first dielectric material, second dielectric material, and third dielectric material are each different from one another.

In further embodiments, the relative permittivity of the first upper dielectric layers 302 is less than the relative permittivity of the second upper dielectric layer 304. By virtue of the upper dielectric structure 216 comprising the first upper dielectric layers 302 and the second upper dielectric layer 304 that each have a high relative permittivity (e.g., greater than about 3.9), the EOT of the first readout gate dielectric structure is relatively low (i.e., less than about 30 angstroms). In an embodiment, the relative permittivity of the lower dielectric layer 214 is about 3.9 and the thickness 215 is about 10 angstroms, the relative permittivity of the first upper dielectric layers 302 is about 9 and the thickness 310 is about 15 angstroms, and the relative permittivity of the second upper dielectric layer 304 is about 25 and the thickness 312 is about 20 angstroms, such that the EOT of the first readout gate dielectric structure 120 is about 26.1 angstroms.

With reference to the cross-sectional view 300e of FIG. 3E, the transfer gate dielectric structure 218, the first readout gate dielectric structure 120, and the second gate dielectric structure 208 respectively comprise the lower dielectric layer 214 and the upper dielectric structure 216, where the upper dielectric structure 216 comprises first upper dielectric layers 302 alternatingly stacked with second upper dielectric layers 304.

With reference to the cross-sectional view 300f of FIG. 3F, the transfer gate dielectric structure 218, the first readout gate dielectric structure 120, and the second readout gate dielectric structure 208 respectively comprise the lower dielectric layer 214 and the upper dielectric structure 216. In some embodiments, the lower dielectric layer 214 comprises a first dielectric material (e.g., silicon dioxide) and has a thickness 215 that may be about 16 angstroms, greater than about 16 angstroms, within a range of about 16 angstroms to about 30 angstroms, or some other suitable value. In various embodiments, the upper dielectric structure 216 comprises a second dielectric material (e.g., hafnium oxide (HfO₂), zirconium oxide (ZrO₂), aluminum oxide (Al₂O₃), silicon nitride (Si₃N₄), etc. and has a thickness 217 that may be about 20 angstroms, about 40 angstroms, less than about 96 angstroms, within a range of about 15 angstroms to about 96 angstroms, or some other suitable value. In various embodiments, the first dielectric material is different from the second dielectric material and the thickness 215 is less than the thickness 217. Further, a relative permittivity of the lower dielectric layer 214 is less than a relative permittivity of the upper dielectric structure 216. For example, the relative permittivity of the lower dielectric layer 214 may be about 3.9 and the relative permittivity of the upper dielectric structure 216 may be about 7 (i.e., the upper dielectric structure 216 comprises silicon nitride). In yet further embodiments, the upper dielectric structure 216 is a single material, where the single material may, for example, be or comprise silicon nitride (Si₃N₄).

With reference to the cross-sectional view 300g of FIG. 3G, the first readout gate dielectric structure 120 comprises the lower dielectric layer 214 and the upper dielectric structure 216. In some embodiments, the lower dielectric layer 214 comprises a first dielectric material (e.g., silicon dioxide) and the upper dielectric structure 216 comprises a second dielectric material (e.g., hafnium oxide (HfO₂), zirconium oxide (ZrO₂), aluminum oxide (Al₂O₃), silicon nitride (Si₃N₄), etc. different from the first dielectric material. In yet further embodiments, the transfer gate dielectric structure 218 and the second readout gate dielectric structure 208 respectively comprises the first dielectric material (e.g., silicon dioxide) or some other suitable material. In such embodiments, a relative permittivity of the upper dielectric structure 216 is greater than relative permittivities of the transfer gate dielectric structure 218 and the second readout gate dielectric structure 208. In yet further embodiments, the transfer gate dielectric structure 218 and the second readout gate dielectric structure 208 are each a single material, where the single material may, for example, be or comprise silicon dioxide or some other suitable material.

Further, thicknesses of the transfer gate dielectric structure 218 and the second readout gate dielectric structure 208 may be less than the thickness of the upper dielectric structure 216. In further embodiments, EOTs of the transfer gate dielectric structure 218 and the second readout gate dielectric structure 208 are greater than the EOT of the first readout gate dielectric structure 120. It will be appreciated that while the first readout gate dielectric structure 120 is configured as illustrated and/or described in FIG. 3A, the first readout gate dielectric structure 120 may be configured as illustrated and/or described in any of FIGS. 3B-3F.

FIG. 4 illustrates a cross-sectional view 400 of some other embodiments of the image sensor of FIGS. 2A and 2B, where the first transistors 108 are each configured as a vertical transistor. In such embodiments, the first transistors 108 each have an upper body over the front side 202f of the imaging substrate 202 and a protrusion extending from the upper body into the imaging substrate 202.

FIG. 5 illustrates a circuit diagram 500 of some other embodiments of the image sensor of FIG. 1, where the image sensor further includes a pixel device chip 502. The imaging chip 102 is electrically coupled to the pixel device chip 502 and the logic chip 104 is electrically coupled to the pixel device chip 502.

In some embodiments, the pixel circuit 112 spans the imaging chip 102 and the pixel device chip 502, where the first transistor 108, the photodetector 106, and the floating diffusion node 110 are disposed on the imaging chip 102 and the plurality of second transistors 114-118 are disposed on the pixel device chip 502. The plurality of second transistors 114-118 comprises the reset transistor 114, the source-follower transistor 116, and the select transistor 118. The logic chip 104 comprises the ASIC circuit 122. By virtue of the pixel circuit 112 spanning the imaging chip 102 and the pixel device chip 502, fewer transistors are disposed on the imaging chip 102. As a result, disposing the second transistors 114-118 on the pixel device chip 502 facilitates scaling down features of the imaging chip 102 and/or increasing a number of photodetectors disposed on the imaging chip 102.

FIG. 6 illustrates a cross-sectional view 600 of some other embodiments of the image sensor of FIGS. 2A and 2B, where the image sensor comprises the imaging chip 102, a pixel device chip 502, and the logic chip 104.

The pixel device chip 502 is disposed between the imaging chip 102 and the logic chip 104. In some embodiments, the pixel device chip 502 comprises a pixel device substrate 604, a pixel device interconnect structure 606, a first pixel device bond structure 610, and a second pixel device bond structure 612. The plurality of second transistors 114-118 is disposed on a front side 604f of the pixel device substrate 604. The plurality of second transistors 114-118 comprises the reset transistor 114, the source-follower transistor 116, and the select transistor 118, and are configured to conduct readout of accumulated charge from the photodetectors 106 of the imaging chip 102. By disposing the second transistors 114-118 on the pixel device substrate 604, for example, instead of on the imaging substrate 202, an area for photodetectors 106 on the imaging substrate 202 is increased, electrical cross-talk across the imaging chip 102 is decreased, and/or features of imaging chip 102 may be further scaled. Accordingly, an overall performance of the image sensor is increased.

Further, by disposing the first transistors 108 on the imaging substrate 202, the first transistors 108 are formed by a separate fabrication process than the plurality of second transistors 114-118. As a result, transfer gate dielectric structures 218 of the first transistors 108 are different from the first readout gate dielectric structure 120 of the source-follower transistor 116. For example, the transfer gate dielectric structures 218 may each comprise a dielectric material (e.g., silicon oxide) with a low relative permittivity (e.g., about 3.9 of less) and have a thickness 601 less than that of the upper dielectric structure 216. In some embodiments, the thickness 601 is within a range of about 20 angstroms to about 70 angstroms or some other suitable value. In various embodiments, EOTs of the transfer gate dielectric structures 218 are greater than the EOT of the first readout gate dielectric structure 120. In various embodiments, the transfer gate dielectric structures 218 may, for example, each consist of or consist essentially of silicon dioxide.

A plurality of through-substrate vias (TSVs) 608 is disposed in the pixel device chip 502. The TSVs continuously extend through the pixel device substrate 604 from the second pixel device bond structure 612 to the pixel device interconnect structure 606. The TSVs 608 are configured to electrically coupled the second pixel device bond structure 612 to the pixel device interconnect structure 606. In some embodiments, the pixel device interconnect structure 606 comprises the interconnect dielectric structure 221, the plurality of conductive vias 222, and the plurality of conductive wires 224. In further embodiments, the first and second pixel device bond structures 610, 612 respectively comprise the bond dielectric structure 230, the plurality of bond contacts 232, and the plurality of bond pads 234. The imaging bond structure 226 and the first pixel device bond structure 610 meet at a first bonding interface. The logic bond structure 228 and the second pixel device bond structure 612 meet at a second bonding interface.

In various embodiments, the imaging chip 102 further comprises a grid structure 620 disposed on the back side 202b of the imaging substrate 202, a plurality of light filters 618 overlying the plurality of photodetectors 106, and a plurality of micro-lenses 622 disposed on the plurality of light filters 618. The light filters 618 each comprise a material configured to pass a first range of wavelengths while blocking a second range of wavelengths. Further, the micro-lenses 622 are configured to direct incident light towards the underlying photodetectors 106.

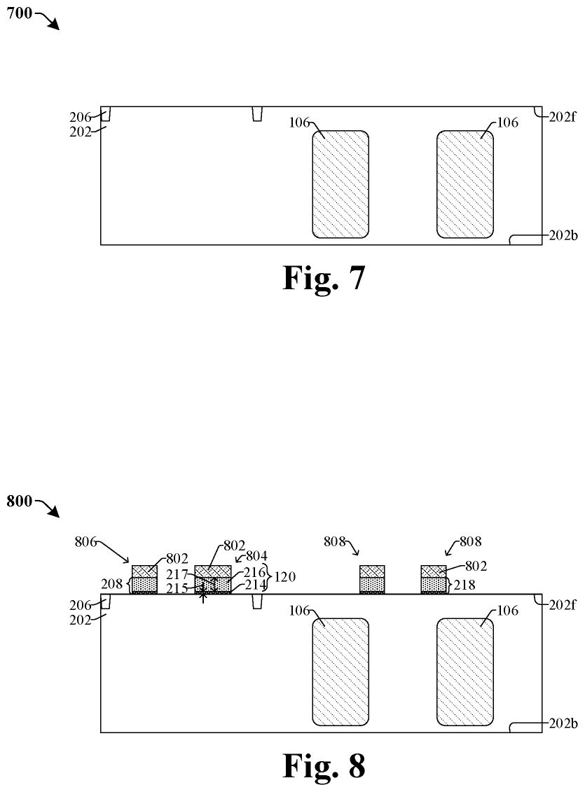

FIGS. 7-18 illustrate various cross-sectional views 700-1800 of some embodiments of a method for forming an image sensor comprising a transistor having a gate dielectric structure with high relative permittivity. Although the cross-sectional views 700-1800 shown in FIGS. 7-18 are described with reference to the method, it will be appreciated that the structures shown in FIGS. 7-18 are not limited to the method but rather may stand alone separate of the method. Furthermore, although FIGS. 7-18 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part.

As shown in cross-sectional view 700 of FIG. 7, a plurality of photodetectors 106 and a first isolation structure 206 are formed within an imaging substrate 202. In some embodiments, a process for forming the photodetectors 106 includes: forming a masking layer (not shown) over a front side 202f of the imaging substrate 202; performing an ion implantation process on the imaging substrate 202 with the masking layer in place, thereby implanting one or more dopants within the imaging substrate 202; and performing a removal process to remove the masking layer. In some embodiments, the imaging substrate 202 has a first doping type (e.g., p-type) and the photodetectors 106 comprise a second doping type (e.g., n-type) opposite the first doping type (e.g., p-type). In further embodiments, a process for forming the first isolation structure 206 includes: forming a masking layer (not shown) over the front side 202f of the imaging substrate 202; patterning the imaging substrate 202 according to the masking layer to form a first isolation trench extending into the imaging substrate 202; depositing (e.g., by physical vapor deposition (PVD), chemical vapor deposition (CVD), atomic layer deposition (ALD), etc.) a dielectric material (e.g., silicon dioxide, silicon nitride, silicon carbide, another dielectric material, or any combination of the foregoing) within the first isolation trench; and performing a removal process to remove the masking layer.

As shown in cross-sectional view 800 of FIG. 8, a plurality of gate structures 804-808 are formed on the front side 202f of the imaging substrate 202. The plurality of gate structures 804-808 comprises first and second readout gate structures 804, 806 and transfer gate structures 808. Each of the gate structures 804-808 comprise a dummy gate electrode structure 802 overlying a corresponding gate dielectric structure 120, 208, 218. For instance, the first readout gate structure 804 comprises a dummy gate electrode structure 802 overlying a first readout gate dielectric structure 120, the second readout gate structure 806 comprises the dummy gate electrode structure 802 overlying a second readout gate dielectric structure 208, and the transfer gate structure 808 comprise the dummy gate electrode structure 802 overlying a transfer gate dielectric structure 218. In some embodiments, a process for forming the plurality of gate structures 804-808 includes: depositing (e.g., by CVD, PVD, ALD, etc.) a lower dielectric layer 214 on the imaging substrate 202; depositing (e.g., by CVD, PVD, ALD, etc.) an upper dielectric structure 216 on the lower dielectric layer; depositing (e.g., by CVD, PVD, ALD, etc.) a dummy gate electrode structure 802 on the upper dielectric structure 216; and performing a patterning process on the lower dielectric layer 214, the upper dielectric structure 216, and the dummy gate electrode structure 802.

In various embodiments, the transfer gate dielectric structure 218, the first readout gate dielectric structure 120, and the second readout gate dielectric structure 208 respectively comprise the lower dielectric layer 214 and the upper dielectric structure 216. In some embodiments, the lower dielectric layer 214 comprises a first dielectric material (e.g., silicon dioxide) and has a thickness 215 that may be about 15 angstroms, less than about 15 angstroms, within a range of about 5 to about 15 angstroms, or some other suitable value. In various embodiments, the upper dielectric structure 216 comprises a second dielectric material (e.g., hafnium oxide (HfO₂), zirconium oxide (ZrO₂), aluminum oxide (Al₂O₃), silicon nitride (Si₃N₄), etc. and has a thickness 217 that may be about 20 angstroms, about 40 angstroms, less than about 96 angstroms, within a range of about 20 angstroms to about 96 angstroms, or some other suitable value. In various embodiments, the first dielectric material is different from the second dielectric material and the thickness 215 is less than the thickness 217. Further, a relative permittivity of the lower dielectric layer 214 is less than a relative permittivity of the upper dielectric structure 216. For example, the relative permittivity of the lower dielectric layer 214 may be about 3.9 and the relative permittivity of the upper dielectric structure 216 may be about 25. In yet further embodiments, the upper dielectric structure 216 is a single material, where the single material may, for example, be or hafnium oxide, silicon nitride, zirconium oxide, or the like. By virtue of the upper dielectric structure 216 having the high relative permittivity, the EOT of the first readout gate dielectric structure 120 is relatively low (i.e., less than about 30 angstroms), thereby increasing noise performance (e.g., by reducing random telegraph noise) and reliability of the image sensor.

In yet further embodiments, it will be appreciated that while the transfer gate dielectric structure 218 and the first and second readout gate dielectric structures 120, 208 are formed comprising the lower dielectric layer 214 and the upper dielectric structure 216 as illustrated and/or described in FIG. 3A, the transfer gate dielectric structure 218 and the first and second readout gate dielectric structures 120, 208 may be formed to be configured as illustrated and/or described in any one of FIGS. 3B-3G.

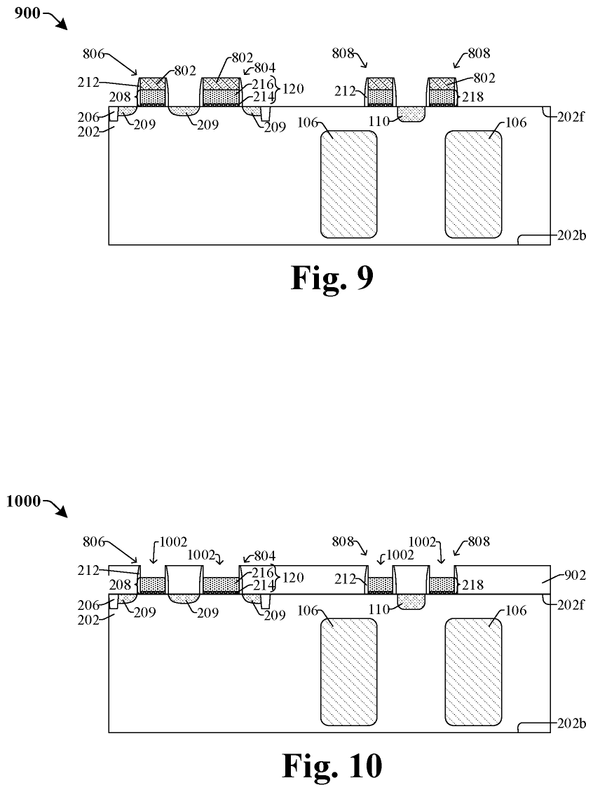

As shown in cross-sectional view 900 of FIG. 9, sidewall spacers 212 are formed along sidewalls of the plurality of gate structures 804-808. In some embodiments, the sidewall spacers 212 are formed by: depositing (e.g., by CVD, PVD, ALD, etc.) a sidewall spacer layer over the front side 202f of the imaging substrate 202 and along sidewalls of the gate structures 804-808; and an etching process is performed to remove the spacer layer from horizontal surfaces. The sidewall spacers 212 may, for example, be or comprise an oxide (e.g., silicon dioxide), silicon nitride, silicon carbide, silicon oxynitride, silicon oxycarbide, some other dielectric material, or any combination of the foregoing.

In addition, as shown in the cross-sectional view 900 of FIG. 9, a plurality of source/drain regions 209 and a floating diffusion node 110 are formed within the imaging substrate 202. In some embodiments, the source/drain regions 209 and the floating diffusion node 110 comprise the second doping type (e.g., n-type). In further embodiments, the source/drain regions 209 and the floating diffusion node 110 are formed by a selective ion implantation process that selectively implants n-type dopants (e.g., phosphorous) into the imaging substrate 202.

As shown in cross-sectional view 1000 of FIG. 10, a first dielectric layer 902 is formed over the front side 202f of the imaging substrate 202. In some embodiments, a process for forming the first dielectric layer 902 includes: depositing (e.g., by CVD, PVD, ALD, etc.) the first dielectric layer 902 over the imaging substrate 202; and performing a planarization process (e.g., a chemical mechanical planarization (CMP) process) on the first dielectric layer 902.

Further, a removal process is performed on the plurality of gate structures 804-808 to remove the dummy gate electrode structures 802 and form a plurality of gate electrode openings 1002. In some embodiments, the removal process includes: forming a masking layer (not shown) over the first dielectric layer 902; performing an etch process (e.g., a wet etch and/or a dry etch) with the masking layer in place; and removing the masking layer.

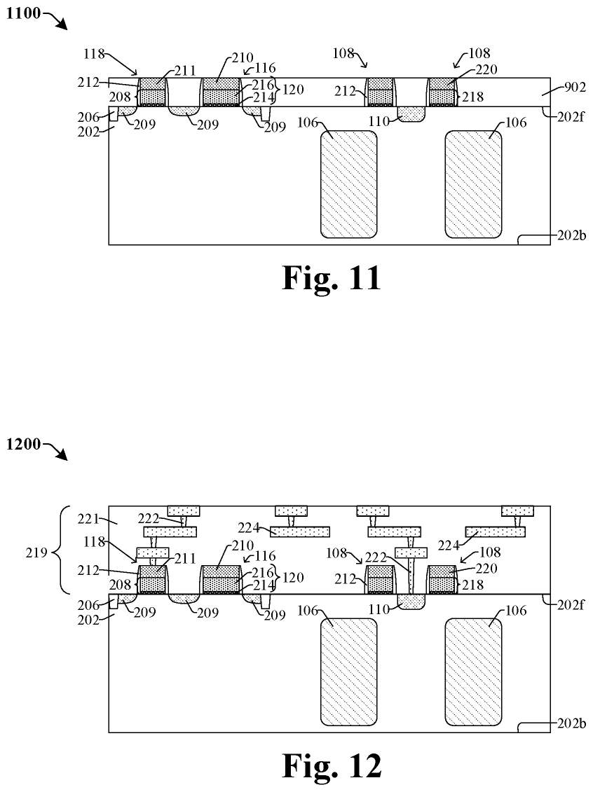

As shown in cross-sectional view 1100 of FIG. 11, first and second readout gate electrodes 210, 211 and transfer gate electrodes 220 are formed within the gate electrode openings (1002 of FIG. 10), thereby defining a plurality of first transistors 108 and a plurality of second transistors 116, 118. In some embodiments, a process for forming the first and second readout gate electrodes 210, 211 and the transfer gate electrodes 220 includes: depositing (e.g., by PVD, CVD, ALD, sputtering, electrode plating, electroless plating, etc.) one or more gate electrode layer(s) within the gate electrode openings (1002 of FIG. 10); and performing a planarization process (e.g., a CMP process, an etching process, etc.) on the one or more gate electrode layer(s). The second transistors 116, 118 comprise a source-follower transistor 116 and a select transistor 118. By virtue of the source-follower transistor 116 comprising the first readout gate dielectric structure 120 with the relatively low EOT (e.g., less than about 30 angstroms), noise performance of the source-follower transistor 116 is improved (e.g., by decreasing random telegraph noise) thereby increasing an overall performance of the image sensor.

In various embodiments, the first and second readout gate electrodes 210, 211, and transfer gate electrodes 220 are formed concurrently with one another. In further embodiments, the first readout gate electrode 210 may be formed by a different process than the second readout gate electrodes 211 and/or the transfer gate electrodes 220. In such embodiments, the first readout gate electrode 210 and/or the first readout gate dielectric structure 120 comprise materials and/or have thicknesses different from that of the second readout gate electrodes 211, the transfer gate electrodes 220, second readout gate dielectric structures 208, and/or transfer gate dielectric structures 218 (e.g., as illustrated and/or described in FIG. 3G). Further, while FIGS. 8-12 illustrate formation of the source-follower transistor 116 and the select transistor 118, it will be appreciated that the reset transistor 114 of FIGS. 2A and 2B may be formed by the same or substantially similar processing steps illustrates and/or described in FIGS. 8-12. In yet further embodiments, while the first and second transistors 108, 116, 118 are formed by a replacement gate process as illustrated by FIGS. 8-12, other fabrication process(es) may be utilized to form the first and second transistors 108, 116, 118. For example, the first and second transistors 108, 116, 118 may be formed by a gate first process.

As shown in cross-sectional view 1200 of FIG. 12, an imaging interconnect structure 219 is formed on the front side 202f of the imaging substrate 202. The imaging interconnect structure 219 comprises an interconnect dielectric structure 221, a plurality of conductive vias 222, and a plurality of conductive wires 224. The imaging interconnect structure 219 may be formed by one or more deposition processes such as a PVD process, a CVD process, an ALD process, another suitable growth or deposition process, or any combination of the foregoing. In yet further embodiments, the first dielectric layer (902 of FIG. 11) is part of the imaging interconnect structure 219. In various embodiments, the plurality of conductive vias 222 and the plurality of conductive wires 224 may be formed by one or more deposition process(es), one or more patterning process(es), one or more planarization process(es), some other suitable fabrication process(es), or any combination of the foregoing.

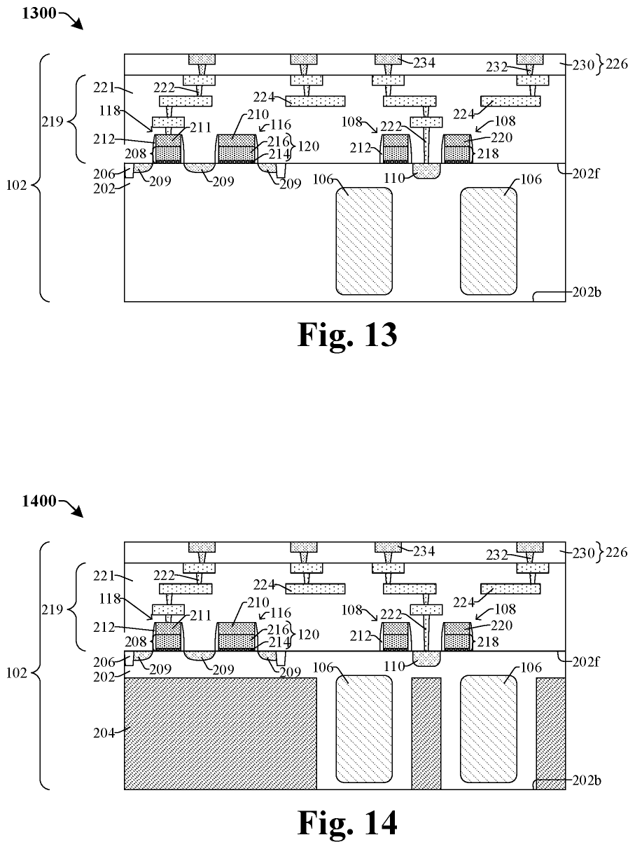

As shown in cross-sectional view 1300 of FIG. 13, an imaging bond structure 226 is formed on the imaging interconnect structure 219, thereby defining an imaging chip 102. In some embodiments, the imaging bond structure 226 comprises a bond dielectric structure 230, a plurality of bond contacts 232, and a plurality of bond pads 234. In some embodiments, the imaging bond structure 226 may be formed by: depositing (e.g., by PVD, CVD, ALD, etc.) one or more dielectric layers (e.g., comprising silicon dioxide, silicon nitride, silicon carbide, silicon oxynitride, etc.) on the imaging interconnect structure 219; etching the one or more dielectric layers to form one or more bond contact holes and/or one or more bond pad trenches in the one or more dielectric layers; filing (e.g., by PVD, CVD, ALD, electroplating, electro-less plating, etc.) the one or more bond contact holes and/or bond pad trenches with a conductive material (e.g., copper, aluminum, tungsten, etc.); and performing a planarization process (e.g., a chemical mechanical planarization (CMP) process) on the conductive material.

As shown in cross-sectional view 1400 of FIG. 14, a second isolation structure 204 is formed extending into a back side 202b of the imaging substrate 202. In some embodiments, a process for forming the second isolation structure 204 includes: selectively etching the back side 202b of the imaging substrate 202 to form a trench disposed between adjacent photodetectors 106; depositing (e.g., by CVD, PVD, ALD, etc.) isolation structure material(s) (e.g., such as a trench fill material and a liner material, where the liner material is disposed between the imaging substrate 202 and the trench fill material) within the trench; and performing a planarization process (e.g., a CMP process, an etching process, etc.) on the isolation structure material(s).

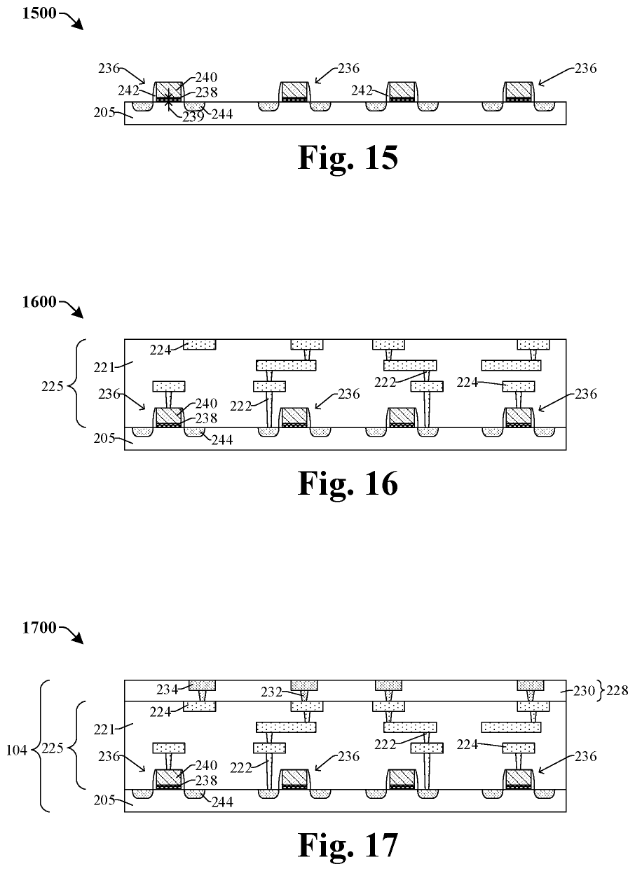

As shown in cross-sectional view 1500 of FIG. 15, a logic substrate 205 is provided and a plurality of logic devices 236 is formed on the logic substrate 205. In some embodiments, a process for forming the plurality of logic devices 236 includes: depositing (e.g., by PVD, CVD, ALD, etc.) a logic gate dielectric over the logic substrate 205; deposition (e.g., by PVD, CVD, sputtering, electroplating, etc.) a logic gate electrode on the logic gate dielectric; performing a patterning process on the logic gate dielectric and the logic gate electrode, thereby defining logic gate dielectric structures 238 and logic gate electrodes 240; forming logic sidewall spacers 242 along sidewalls of the logic gate dielectric structures 238 and sidewalls of the logic gate electrodes 240; and performing a selective ion implantation process to form source/drain regions 244 on opposing sides of each logic gate electrode 240. In some embodiments, the logic gate dielectric structure 238 comprises a single dielectric material (e.g., silicon oxide) with a low relative permittivity (e.g., about 3.9 or less). In such embodiments, a thickness 239 of the logic gate dielectric structure 238 is within a range of about 22 angstroms to about 70 angstroms, or some other suitable value.

As shown in cross-sectional view 1600 of FIG. 16, a logic interconnect structure 225 is formed over the plurality of logic devices 236. In some embodiments, the logic interconnect structure 225 comprises an interconnect dielectric structure 221, a plurality of conductive vias 222, and a plurality of conductive wires 224. The logic interconnect structure 225 may be formed as illustrated and/or described in FIG. 12.

As shown in cross-sectional view 1700 of FIG. 17, a logic bond structure 228 is formed on the logic interconnect structure 225, thereby defining a logic chip 104. In some embodiments, the logic bond structure 228 comprises a bond dielectric structure 230, a plurality of bond contacts 232, and a plurality of bond pads 234. The logic bond structure 228 may be formed as illustrated and/or described in FIG. 13.

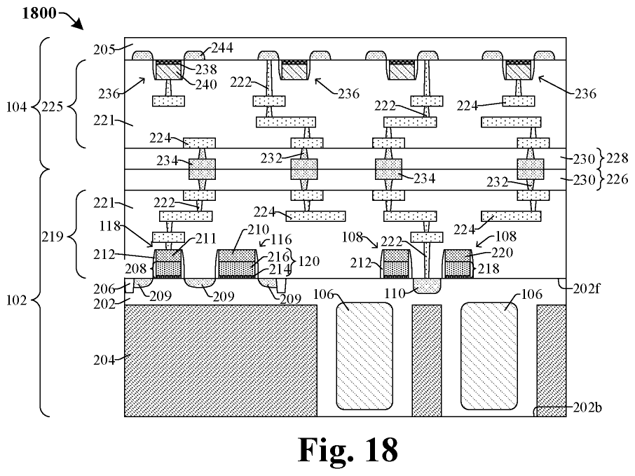

As shown in cross-sectional view 1800 of FIG. 18, the logic chip 104 is flipped and bonded to the imaging chip 102. In some embodiments, the logic chip 104 is bonded to the imaging chip 102 by way of a dielectric-to-dielectric bonding process, a metal-to-metal bonding process, some other suitable bonding process, or any combination of the foregoing.

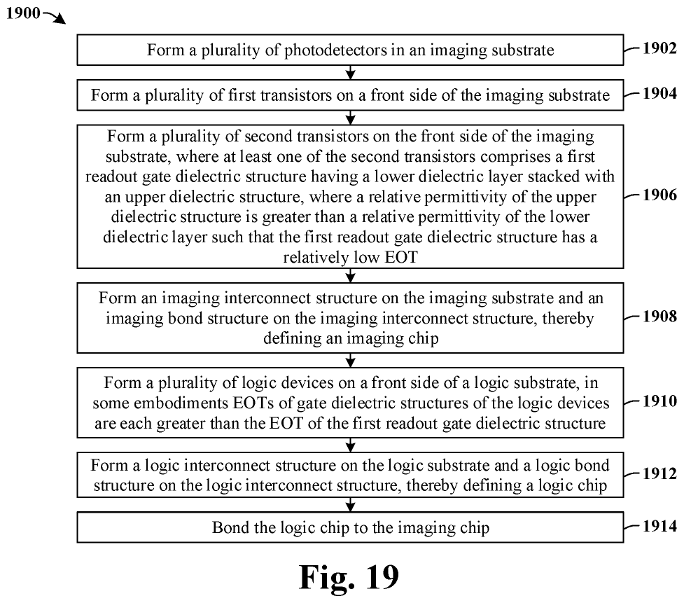

FIG. 19 illustrates some embodiments of a method 1900 for forming an image sensor comprising a readout transistor with a gate dielectric structure having a relatively low EOT. Although the method 1900 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1902, a plurality of photodetectors is formed in an imaging substrate. FIG. 7 illustrates a cross-sectional view 700 corresponding to some embodiments of act 1902.

At act 1904, a plurality of first transistors is formed on a front side of the imaging substrate. FIGS. 8-11 illustrate various cross-sectional views 800-1100 corresponding to some embodiments of act 1904.

At act 1906, a plurality of second transistors is formed on the front side of the imaging substrate, where at least one of the second transistors comprises a first readout gate dielectric structure having a lower dielectric layer stacked with an upper dielectric structure. A relative permittivity of the upper dielectric structure is greater than a relatively permittivity of the lower dielectric layer such that the first readout gate dielectric structure has a relatively low EOT. FIGS. 8-11 illustrate various cross-sectional views 800-1100 corresponding to some embodiments of act 1906.

At act 1908, an imaging interconnect structure is formed on the imaging substrate and an imaging bond structure is formed on the imaging interconnect structure, thereby defining an imaging chip. FIGS. 12 and 13 illustrate cross-sectional views 1200 and 1300 corresponding to some embodiments of act 1908.

At act 1910, a plurality of logic devices is formed on a front side of a logic substrate. In some embodiments, EOTs of gate dielectric structures of the logic devices are each greater than the EOT of the first readout gate dielectric structure. FIG. 15 illustrates a cross-sectional view 1500 corresponding to some embodiments of act 1910.

At act 1912, a logic interconnect structure is formed on the logic substrate and a logic bond structure is formed on the logic interconnect structure, thereby defining a logic chip. FIGS. 16 and 17 illustrate cross-sectional views 1600 and 1700 corresponding to some embodiments of act 1912.

At act 1914, the logic chip is bonded to the imaging chip. FIG. 18 illustrates cross-sectional view 1800 corresponding to some embodiments of act 1914.

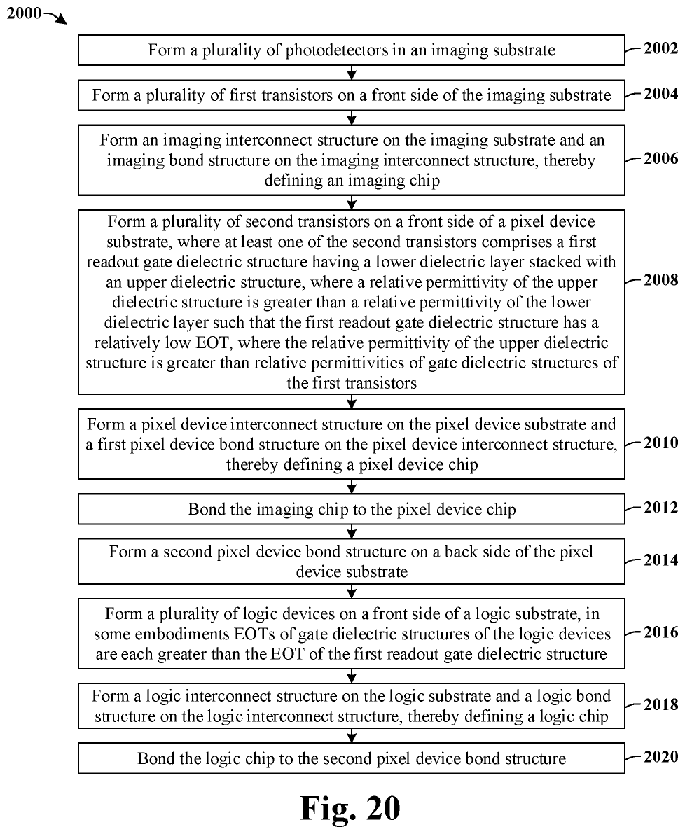

FIG. 20 illustrates some other embodiments of a method 2000 for forming an image sensor comprising a transistor having a gate dielectric structure with high relative permittivity. In some embodiments, the image sensor may be the image sensor of FIG. 5 or 6. Although the method 2000 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 2002, a plurality of photodetectors is formed in an imaging substrate. The plurality of photodetectors may be formed as illustrated and/or described in cross-sectional view 700 of FIG. 7.

At act 2004, a plurality of first transistors is formed on a front side of the imaging substrate. The plurality of first transistors may be formed by process(es) substantially similar to process(es) described above regarding formation of the structure of the cross-sectional view 1100 of FIG. 11 (e.g., see FIGS. 8-11), where gate dielectric structures of the plurality of first transistors are formed to be configured as the transfer gate dielectric structure 218 as illustrated and/or described in FIG. 6.

At act 2006, an imaging interconnect structure is formed on the imaging substrate and an imaging bond structure is formed on the imaging interconnect structure, thereby defining an imaging chip. The imaging interconnect structure and the imaging bond structure may be formed as illustrated and/or described in cross-sectional views 1200 and 1300 of FIGS. 12 and 13.

At act 2008, a plurality of second transistors is formed on a front side of a pixel device substrate, where at least one of the second transistors comprises a first readout gate dielectric structure having a lower dielectric layer stacked with an upper dielectric structure. A relative permittivity of the upper dielectric structure is greater than a relative permittivity of the lower dielectric layer such that the first readout gate dielectric structure has a relatively low EOT. Further, the relative permittivity of the upper dielectric structure is greater than relative permittivities of gate dielectric structures of the first transistors. The second transistors may be formed as illustrated and/or described in cross-sectional views 800-1100 of FIGS. 8-11.

At act 2010, a pixel device interconnect structure is formed on the pixel device substrate and a first pixel device bond structure is formed on the pixel device interconnect structure, thereby defining a pixel device chip. The pixel device interconnect structure and the first pixel device bond structure may be formed by process(es) substantially similar to process(es) described above regarding formation of the imaging interconnect structure 219 and the imaging bond structure 226 of FIGS. 12 and 13.

At act 2012, the imaging chip is bonded to the pixel device chip. The imaging chip may be bonded to the pixel device chip by process(es) substantially similar to process(es) described above in cross-sectional view 1800 of FIG. 18.

At act 2014, a second pixel device bond structure is formed on a back side of the pixel device substrate. The second pixel device bond structure may be formed by process(es) substantially similar to process(es) described above regarding formation of the imaging bond structure 226 of FIG. 13.

At act 2016, a plurality of logic devices is formed on a front side of a logic substrate. In some embodiments, EOTs of gate dielectric structures of the logic devices are each greater than the EOT of the first readout gate dielectric structure. The plurality of logic devices may be formed as illustrated and/or described in cross-sectional view 1500 of FIG. 15.

At act 2018, a logic interconnect structure is formed on the logic substrate and a logic bond structure is formed on the logic interconnect structure, thereby defining a logic chip. The logic interconnect structure and the logic bond structure may be formed as illustrated and/or described in cross-sectional views 1600 and 1700 of FIGS. 16 and 17.

At act 2020, the logic chip is bonded to the second pixel device bond structure. The logic chip may be bonded to the second pixel device bond structure by process(es) substantially similar to process(es) described above in cross-sectional view 1800 of FIG. 18.

Accordingly, in some embodiments, the present disclosure relates to an image sensor comprising a readout transistor with a gate dielectric structure having high relative permittivity.

In some embodiments, the present application provides an image sensor including: a first chip comprising a first substrate and a photodetector disposed in the first substrate; a first transistor disposed on the first substrate and neighboring the photodetector; a second chip stacked with the first chip; and a plurality of second transistors disposed within or on the stacked first and second chips, wherein the plurality of second transistors comprises a first readout transistor having a first readout gate electrode over a first readout gate dielectric structure, wherein the first readout gate dielectric structure comprises a lower dielectric layer stacked with an upper dielectric structure, wherein a relative permittivity of the upper dielectric structure is greater than a relative permittivity of the lower dielectric layer.

In some embodiments, the present application provides an image sensor comprising: a first chip comprising a first substrate and a plurality of photodetectors disposed within the first substrate; a plurality of first transistors disposed on the first substrate, wherein the first transistors respectively comprise a first gate dielectric structure; a second chip stacked with the first chip and comprising a second substrate; and a plurality of second transistors disposed on the second substrate, wherein the plurality of second transistors comprises a first readout transistor having a first readout gate dielectric structure comprising an upper dielectric structure, wherein the upper dielectric structure has a relative permittivity greater than a relative permittivity of the first gate dielectric structure.

In various embodiments, the present application provides a method for forming an image sensor, the method comprising: forming a photodetector within a first substrate; forming a first transistor on the first substrate adjacent to the photodetector; forming a plurality of second transistors over the first substrate, wherein the second transistors comprise a first readout transistor having a first readout gate dielectric structure comprising a lower dielectric layer stacked with an upper dielectric structure, wherein a relative permittivity of the upper dielectric structure is greater than a relative permittivity of the lower dielectric layer, and wherein a thickness of the upper dielectric structure is greater than a thickness of the lower dielectric layer; forming a third transistor on a second substrate, wherein the third transistor has a gate dielectric structure with a relative permittivity less than the relative permittivity of the upper dielectric structure; and bonding the second substrate to the first substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor comprising:
a first chip comprising a first substrate and a photodetector disposed in the first substrate;
a first transistor disposed on the first substrate and neighboring the photodetector;
a second chip stacked with the first chip; and
a plurality of second transistors disposed within or on the stacked first and second chips, wherein the plurality of second transistors comprises a first readout transistor having a first readout gate electrode over a first readout gate dielectric structure, wherein the first readout gate dielectric structure comprises a lower dielectric layer stacked with an upper dielectric structure, wherein a relative permittivity of the upper dielectric structure is greater than a relative permittivity of the lower dielectric layer.

2. The image sensor of claim 1, wherein the relative permittivity of the lower dielectric layer is about 3.9.

3. The image sensor of claim 2, wherein a thickness of the lower dielectric layer is less than a thickness of the upper dielectric structure.

4. The image sensor of claim 1, wherein the first transistor comprises a gate electrode over a gate dielectric structure, wherein a relative permittivity of the gate dielectric structure of the first transistor is less than the relative permittivity of the upper dielectric structure.

5. The image sensor of claim 4, wherein an equivalent oxide thickness (EOT) of the first readout gate dielectric structure is less than an EOT of the gate dielectric structure of the first transistor.

6. The image sensor of claim 5, wherein a height of the gate dielectric structure of the first transistor is less than a height of the first readout gate dielectric structure.

7. The image sensor of claim 1, wherein the first readout transistor is configured as a source-follower transistor.

8. The image sensor of claim 1, wherein the first and second transistors are disposed on a front side of the first substrate, wherein a third transistor is disposed on a second substrate of the second chip, wherein the third transistor comprises a gate dielectric structure having a relative permittivity that is less than, higher than, or equal to the relative permittivity of the upper dielectric structure, wherein a thickness of the gate dielectric structure of the third transistor is less than, higher than, or equal to a thickness of the upper dielectric structure.

9. The image sensor of claim 1, wherein the upper dielectric structure comprises a first upper dielectric layer and a second upper dielectric layer, wherein thicknesses of the first and second upper dielectric layers are greater than a thickness of the lower dielectric layer, wherein a relative permittivity of the first upper dielectric layer is less or higher than a relative permittivity of the second upper dielectric layer.

10. The image sensor of claim 9, wherein the upper dielectric structure further comprises a third upper dielectric layer, wherein a relative permittivity of the third upper dielectric layer is greater or less than the relative permittivity of the lower dielectric layer, wherein the first, second, and third upper dielectric layers each comprise different dielectric materials from one another.

11. The image sensor of claim 1, wherein the plurality of second transistors comprises a second readout transistor having a second readout gate electrode over a second readout gate dielectric structure, wherein a relative permittivity of the second readout gate dielectric structure is less than the relative permittivity of the upper dielectric structure, and wherein a thickness of the second readout gate dielectric structure is less than a thickness of the upper dielectric structure.

12. An image sensor comprising:
a first chip comprising a first substrate and a plurality of photodetectors disposed within the first substrate;
a plurality of first transistors disposed on the first substrate, wherein the first transistors respectively comprise a first gate dielectric structure;
a second chip stacked with the first chip and comprising a second substrate; and
a plurality of second transistors disposed on the second substrate, wherein the plurality of second transistors comprises a first readout transistor having a first readout gate dielectric structure comprising an upper dielectric structure, wherein the upper dielectric structure has a relative permittivity greater than a relative permittivity of the first gate dielectric structure.

13. The image sensor of claim 12, further comprising:
a third chip stacked with the second chip and comprising a third substrate; and
a third transistor disposed on the third chip, wherein a gate dielectric structure of the third transistor has a relative permittivity less than, higher than, or equal to the relative permittivity of the upper dielectric structure.

14. The image sensor of claim 13, wherein the first readout gate dielectric structure further comprises a lower dielectric layer underlying the upper dielectric structure, wherein a relative permittivity of the lower dielectric layer is equal to the relative permittivity of the first gate dielectric structure and is equal to or less than the relative permittivity of the gate dielectric structure of the third transistor.

15. The image sensor of claim 14, wherein an equivalent oxide thickness (EOT) of the first readout gate dielectric structure is less than an EOT of the first gate dielectric structure and an EOT of the gate dielectric structure of the third transistor.

16. The image sensor of claim 12, wherein the plurality of second transistors comprises a select transistor disposed on the second substrate and adjacent to the first readout transistor, wherein the select transistor comprises a second readout gate dielectric structure having a relative permittivity less than the relative permittivity of the upper dielectric structure, wherein a thickness of the second readout gate dielectric structure is less than a thickness of the first readout gate dielectric structure.

17. A method for forming an image sensor, the method comprising:
forming a photodetector within a first substrate;
forming a first transistor on the first substrate adjacent to the photodetector;
forming a plurality of second transistors over the first substrate, wherein the second transistors comprise a first readout transistor having a first readout gate dielectric structure comprising a lower dielectric layer stacked with an upper dielectric structure, wherein a relative permittivity of the upper dielectric structure is greater than a relative permittivity of the lower dielectric layer, and wherein a thickness of the upper dielectric structure is greater than a thickness of the lower dielectric layer;
forming a third transistor on a second substrate, wherein the third transistor has a gate dielectric structure with a relative permittivity less than the relative permittivity of the upper dielectric structure; and
bonding the second substrate to the first substrate.

18. The method of claim 17, wherein the first transistor and the plurality of second transistors are formed concurrently with one another.

19. The method of claim 17, wherein a thickness of the gate dielectric structure of the third transistor is less than the thickness of the upper dielectric structure.

20. The method of claim 17, wherein the upper dielectric structure comprises a first upper dielectric layer stacked with a second upper dielectric layer, wherein a relative permittivity of the first upper dielectric layer is less or higher than a relative permittivity of the second upper dielectric layer.
